(19) United States
(12) Patent Application Publication
(10) Pub. No.: US 2026/0076002 A1
(43) Pub. Date: Mar. 12, 2026

(54) THIN FILM LED PACKAGE WITHOUT SUBSTRATE CARRIER

(71) Applicant: LUMILEDS LLC, San Jose, CA (US)

(72) Inventors: Grigoriy Basin, San Francisco, CA (US); Phillip Barton, Santa Clara, CA (US)

(21) Appl. No.: 19/139,118

(22) PCT Filed: Dec. 13, 2023
(86) PCT No.: PCT/US2023/083759

§ 371 Date: Jun. 13, 2025

Related U.S. Application Data
(60) Provisional application No. 63/433,085, filed on Dec. 16, 2022.

(51) Int. Cl. H10H 29/01; H10H 29/24; H10H 29/85

(52) U.S. Cl. CPC H10H 29/0362; H10H 29/0363; H10H 29/24; H10H 29/857

(57) ABSTRACT

A thin film light emitting diode (LED) package for high power applications and method of fabricating the LED package are described. The epitaxial growth substrate is removed and a molding compound is used as underfill to substantially completely fill the space between under bump metallization (UBM) under the remaining semiconductor stack. The molding compound provides mechanical support for the LED package during processing after the epitaxial growth substrate is removed. A temporary adhesive layer and frame is used to support the semiconductor stack and is removed after processing. A reflective material is disposed between LED die after removing the growth substrate. A conversion layer deposited on the semiconductor stack converts light emitted by the semiconductor stack to light of one or more other wavelengths.

### PRIORITY CLAIM

This application claims the benefit of priority to U.S. Provisional Patent Application Ser. No. 63/433,085, filed Dec. 16, 2022, which is incorporated herein by reference in its entirety.

### FIELD OF THE DISCLOSURE

The present disclosure relates to light emitting diode (LED) structures. In particular, embodiments are directed to thin film LED packages in which the substrate has been removed.

### BACKGROUND OF THE DISCLOSURE

There is ongoing effort to improve thin film LED packages. In particular, it is desirable to improve manufacturing of high power thin film LED packages.

### BRIEF DESCRIPTION OF THE DRAWINGS

FIG. 1 shows an illumination apparatus, in accordance with some examples.

FIG. 2A illustrates a cross-sectional view of an LED package during fabrication, in accordance with some examples.

FIG. 2B illustrates a cross-sectional view of an LED package after the operations shown in FIG. 2A, in accordance with some examples.

FIG. 2C illustrates a cross-sectional view of an LED package after the operations shown in FIG. 2B, in accordance with some examples.

FIG. 2D illustrates a cross-sectional view of an LED package after the operations shown in FIG. 2C, in accordance with some examples.

FIG. 2E illustrates a cross-sectional view of an LED package after the operations shown in FIG. 2D, in accordance with some examples.

FIG. 2F illustrates a cross-sectional view of an LED package after the operations shown in FIG. 2E, in accordance with some examples.

FIG. 2G illustrates a cross-sectional view of an LED package after the operations shown in FIG. 2F, in accordance with some examples.

FIG. 2H illustrates a cross-sectional view of an LED package after the operations shown in FIG. 2G, in accordance with some examples.

FIG. 2I illustrates a cross-sectional view of an LED package after the operations shown in FIG. 2H, in accordance with some examples.

FIG. 2J illustrates a cross-sectional view of an LED package after the operations shown in FIG. 2I, in accordance with some examples.

FIG. 3 illustrates an example of an electronic device in accordance with some embodiments.

FIG. 4 illustrates an example lighting system, according to some embodiments.

FIG. 5 illustrates an example hardware arrangement for implementing the above disclosed subject matter, according to some embodiments.

FIG. 6 illustrates an example hardware arrangement for implementing the above disclosed subject matter, according to some embodiments.

FIG. 7 illustrates an example method of fabricating an LED device, according to some embodiments.

### DETAILED DESCRIPTION

A thin film LED package for high power applications and method of fabricating the LED package are described. The thin film LED package has removed a substrate on which a semiconductor stack was fabricated and uses a molding compound as underfill substantially completely filling the space between under bump metallization (UBM) under the remaining semiconductor stack. The molding compound provides mechanical support for the LED package during processing after the substrate has been removed and subsequently after completion of the LED package.

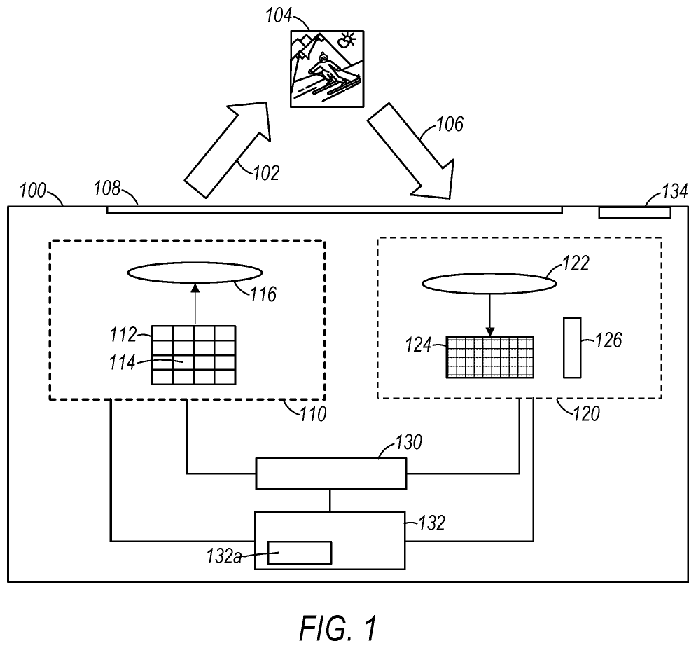

FIG. 1 shows an illumination apparatus 100, in accordance with some examples. The illumination apparatus 100 may be, for example, a smart phone or standalone camera that contains an adaptive LED light source. The illumination apparatus 100 may include both a light source 110 and a camera 120. The camera 120 may capture an image of a scene 104 during an exposure duration of the camera 120, whether or not the scene 104 is illuminated by the light source 110. A processor 130 may be used to control various functions of the light source 110 and the camera 120, including whether or not a shutter is open in an opening 108 of a housing of the illumination apparatus 100.

The opening 108 may be a single opening as shown in FIG. 1 or may include multiple separate openings. Similarly, the shutter may be a single shutter that covers both the light source 110 and the camera 120 or may include multiple separate shutters that covers only one of the light source 110 or the camera 120 and are individually controllable by the processor 130.

The illumination apparatus 100 may include one or more LED arrays 112. Each of the one or more LED arrays 112 may include a plurality of LEDs 114 that may produce light during at least a portion of the exposure duration of the camera 120. Each of the one or more LED arrays 112 may contain segmented LEDs 114 in which the LEDs 114 are divided into a grid of light emitting areas (the LEDs 114) and non-light emitting areas (between the LEDs 114). In some embodiments, the effect of the non-light emitting areas on the image captured using the one or more LED arrays 112 may be compensated for by moving the one or more LED arrays 112 and/or at least one lens 116 using one or more actuators during the exposure duration of the scene 104 to shift the LEDs 114 slightly to illuminate the areas of the scene 104 that would be subject to the non-light emitting areas.

Each of the LEDs 114 may be formed using one or more inorganic semiconductor materials (e.g., binary compounds such as gallium arsenide (GaAs) or gallium nitride (GaN), ternary compounds such as aluminum gallium arsenide (AlGaAs), quaternary compounds such as indium gallium phosphide (InGaAsP)), or other suitable materials. The LEDs 114 are typically either III-V materials (defined by columns of the Periodic Table) or II-VI materials. Each of the LEDs 114 may emit light in the visible spectrum (about 400 nm to about 780 nm) or may also emit light in the infrared spectrum (above about 780 nm). In some embodiments, one or more other layers, such as a phosphor layer may be disposed on each of the one or more LED arrays 112 to convert the light from the LEDs 114 into white (or another color) light. LEDs 114 in a particular LED array 112 that emit light in the infrared spectrum may be, for example, interspersed with LEDs 114 may emit light in the visible spectrum, or each type of LED (visible emitter/infrared emitter) may be disposed on different sections of the particular LED array 112. Alternatively, each LED array 112 may only emit light in either the visible spectrum or the infrared spectrum; separate (one or more) LED arrays may be used to emit light in the infrared spectrum, each of the individual LED array 112, LEDs 114 and/or LED segments controllable by the processor 130.

Each of the one or more LED arrays 112 may be, for example, micro-LED array, the latter of which includes thousands to millions of microscopic LEDs 114 that may emit light and that may be individually controlled or controlled in groups of pixels (e.g., 5×5 groups of pixels). MicroLEDs are relatively small (e.g., <0.01 mm on a side) compared to typical LEDs and may provide monochromatic or multi-chromatic light, typically red, green, or blue using inorganic semiconductor material such as that indicated above.

The light source 110 may include at least one lens 116 and/or other optical elements such as reflectors. The lens 116 and/or other optical elements may direct the light emitted by the one or more LED arrays 112 toward the scene 104 as illumination 102.

The camera 120 may sense light at least the wavelength or wavelengths emitted by the one or more LED arrays 112. Similar to the light source 110, the camera 120 may include optics (e.g., at least one camera lens 122) that are able to collect reflected light 106 of the illumination 102 that is reflected from and/or emitted by the scene 104. The camera lens 122 may direct the reflected light 106 onto a multi-pixel sensor 124 (also referred to as a light sensor) to form an image of the scene 104 on the multi-pixel sensor 124.

The processor 130 may receive a data signal that represents the image of the scene 104. The processor 130 may additionally control and drive the LEDs 114 in the one or more LED arrays 112 via one or more drivers 132. For example, the processor 130 may optionally control one or more LEDs 114 in the one or more LED arrays 112 independent of another one or more LEDs 114 in the one or more LED arrays 112, so as to illuminate the scene in a specified manner.

In addition, one or more detectors 126 may be incorporated in the camera 120. In other embodiments, instead of being incorporated in the camera 120, the one or more detectors 126 may be incorporated in one or more different areas, such as the light source 110 or elsewhere close to the camera 120. The one or more detectors 126 may include multiple different sensors to sense visible and/or infrared light (e.g., from the scene 104), and may further sense the ambient light and/or variations/flicker in the ambient light in addition to reception of the reflected light from the LEDs 114. The multi-pixel sensor 124 of the camera 120 may be of higher resolution than the sensors of the one or more detectors 126 to obtain an image of the scene with a desired resolution. The sensors of the one or more detectors 126 may have one or more segments (that are able to sense the same wavelength/range of wavelengths or different wavelength/range of wavelengths), similar to the LED arrays 112. In some embodiments, if multiple detectors are used, one or more of the detectors may detect visible wavelengths and one or more of the detectors may detect infrared wavelengths; like the one or more LED arrays 112, the one or more detectors 126 may be individually controllable by the processor 130.

In some embodiments, instead of, or in addition to, being provided in the camera 120, one or more of the sensors of the one or more detectors 126 may be provided in the light source 110. In some embodiments, the light source 110 and the camera 120 may be integrated in a single module, while in other embodiments, the light source 110 and the camera 120 may be separate modules that are disposed on a PCB. In other embodiments, the light source 110 and the camera 120 may be attached to different PCBs-for example, as the camera 120 may be thicker than the light source 110, which may result in design issues if the light source 110 and the camera 120 are attached to the same PCB. In the latter embodiment, multiple openings may be present in the housing at least one of which may be eliminated with the use of an integrated light source 110 and camera 120.

The LEDs 114 may be driven using a direct current (DC) driver or pulse width modulation (PWM). Using DC driving may encounter color differences if the segmented one or more LED arrays 112 is driven at different current densities, while PWM driving may generate artifacts due to ambient lighting conditions. The flicker sensor, if present, may sense the variation of artificial lighting at the wall current frequency or electronic ballasts frequencies (e.g., 50 Hz or 60 Hz or an integral multiple thereof), in addition to the phase of the flicker. The camera sensor is then tuned to an integration time of an integral multiple of the time period (1/f) or triggered at the phase where the illumination changes most slowly (minimum or maximum intensity, with the maximum intensity preferred for signal-to-noise ratio considerations). The LEDs 114 may be driven using a PWM whose phase shift varies between LEDs 114 to reduce potential current surge issues. As shown, one or more drivers 132 may be used to drive the LEDs 114 in the one or more LED arrays 112, as well as other components, such as the actuators.

The illumination apparatus 100 may also include an input device 134, for example, a user-activated input device such as a button that is depressed to take a picture. The light source 110 and camera 120 may be disposed in a single housing.

As above, the light source 110 of FIG. 1 may contain individually addressable LED segments to allow selective illumination of the scene 104. For array sizes larger than 3×3 matrices, the LED segments may be combined with an integrated driver to allow the function of individual addressability and obtain the small form factor desired for mobile devices without creating issues in layout of the semiconductor layers used to create the integrated devices. LEDs or microLEDs can be used in the illumination apparatus 100 shown in FIG. 1 to form different types of displays, LED matrices and light engines including adaptive automotive headlights, AR, VR, or mixed-reality (MR) headsets, smart glasses, and displays for mobile phones, smart watches, monitors and TVs. The individual LED pixels in these architectures may have an area of few square millimeters down to few square micrometers depending on the matrix or display size and pixel-per-inch requirements.

Some of the applications above, such as automotive or camera flash applications, may use thin film LED packages that provide relatively high power light (greater than about 1 W). The LED package may contain one or more LEDs in an LED array. Each LED may contain a semiconductor structure fabricated using epitaxial semiconductor deposition (e.g., metal organic chemical vapor deposition) on a growth substrate, such as sapphire, to deposit one or more semiconductor layers. Other fabrication processes during fabrication may include metal deposition (e.g., by sputtering, plating, or evaporation), oxide growth, as well as etching, liftoff, and cleaning, among others. The semiconductor deposition may be used to create an LED with an active region in which electron-hole recombination occurs and the light from the LED is generated. The active region may be, for example, one or more quantum wells.

During fabrication, the semiconductor structure and substrate may be attached by a permanent connection to a substrate carrier, which may become a part of the LED package. The permanent connection may be a gold-gold interconnect (GGI) or solder, for example; the substrate carrier may be a ceramic or metal core printed circuit board (MCPCB), for example. However, such an arrangement may be problematic in situations in which individualized customer platforms are desired for the LED package or in embodiments in which multiple LEDs are located in close proximity to each other.

In some embodiments, LEDs are attached to the substrate carrier and only after this attachment is underfill of a mold resin applied to maintain the robustness of the epitaxial layers for the future processing. These later processing operations may include laser lift off (LLO) or Ga removal (GaR), for example. As a result, the final LED package includes the substrate as a substantial part of the overall structure. Unless otherwise indicated, removal of a structure removes essentially all of the structure.

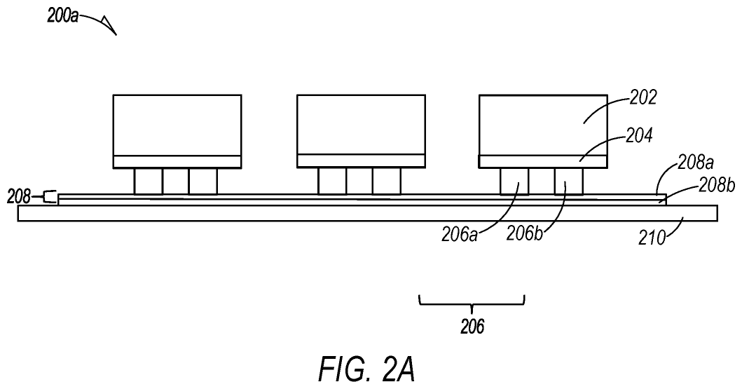

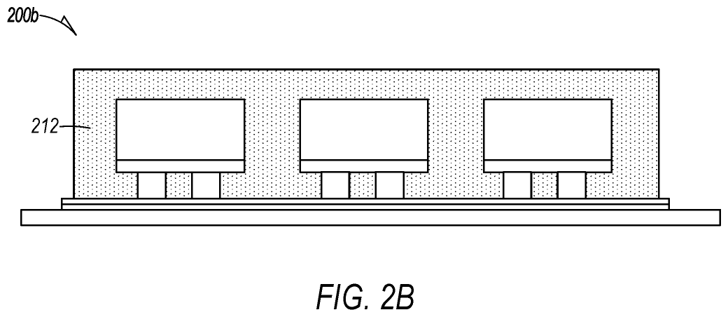

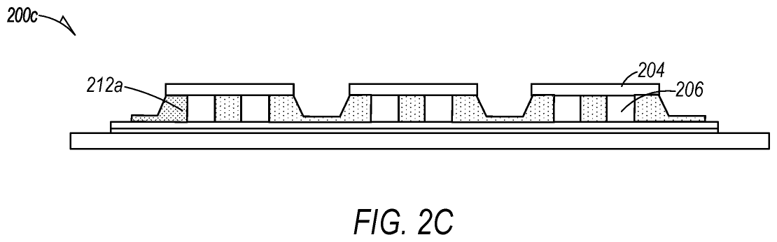

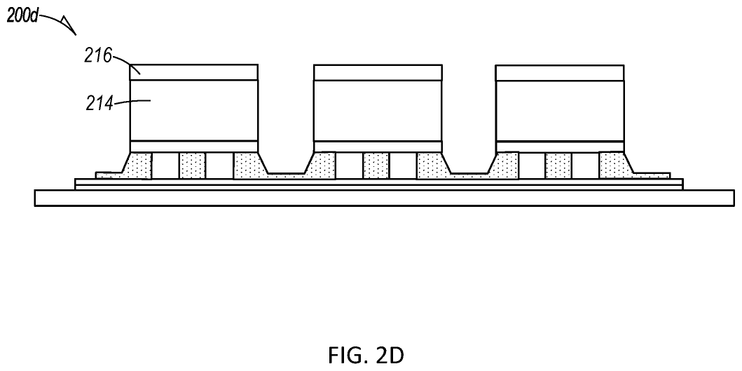

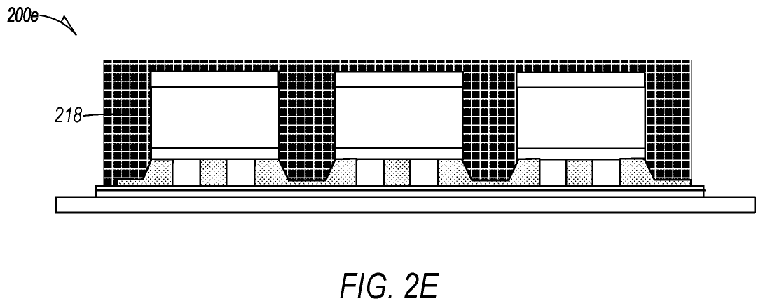

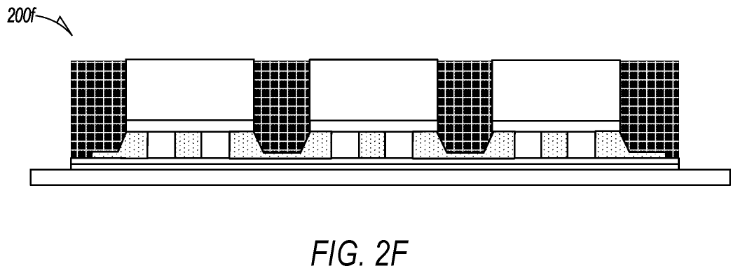

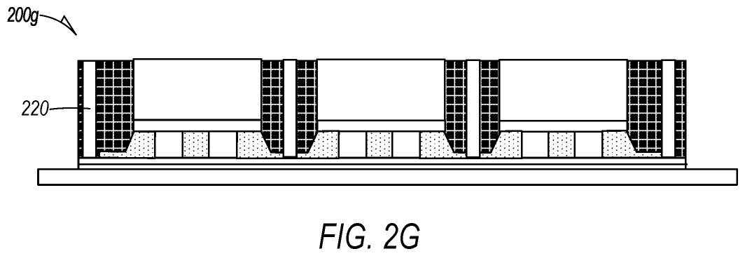

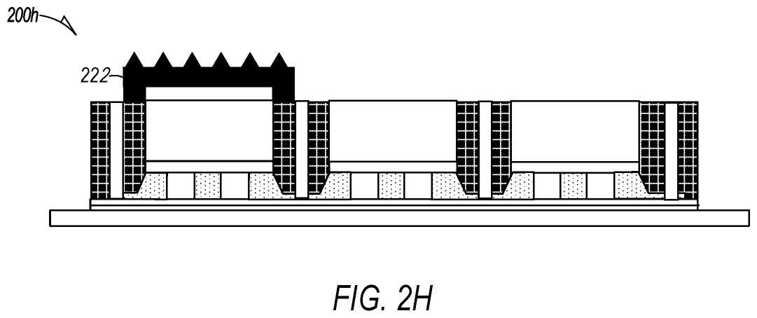

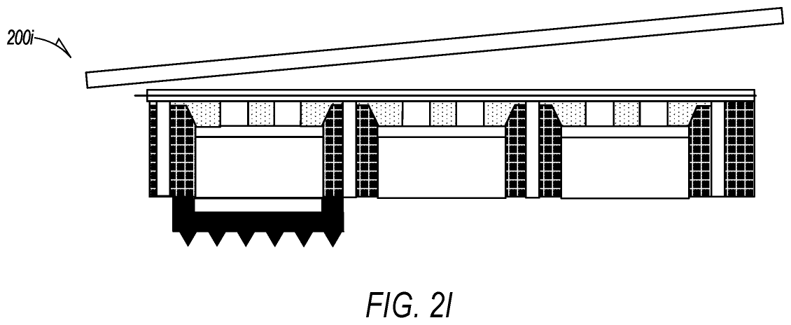

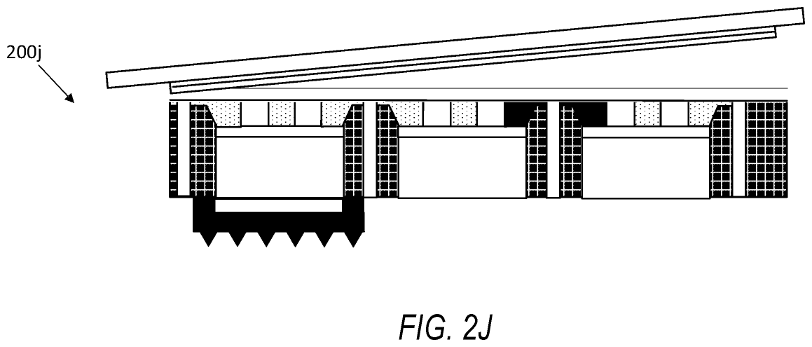

FIGS. 2A-2J illustrate cross-sectional views of fabrication of an LED package. FIG. 2A illustrates a cross-sectional view of an LED package during fabrication, in accordance with some examples. Not all of the operations are shown in FIGS. 2A-2J; other operations such as wafer cleaning may be used but are not described for brevity. The LED package 200a includes a semiconductor stack 204 that has been epitaxially grown on a substrate 202. The semiconductor stack 204 may be designed to emit light of a particular wavelength. In some embodiments, the semiconductor stack 204 may be a GaN-based semiconductor structure that emits blue light. The semiconductor stack 204 may have a height, for example, in the range of about 6 μm. The substrate 202 may be sapphire, and may be for about 120 μm to about 150 μm, for example.

The anode of the semiconductor stack 204 may be electrically coupled to an anode UBM 206a and the cathode of the semiconductor stack 204 may be electrically coupled to a cathode UBM 206b. The UBM 206 (which includes both the anode UBM 206a and the cathode UBM 206b) may patterned and formed from a metal, such as copper (Cu), nickel (Ni), gold (Au), silver (Ag), and/or titanium (Ti), for example, which may be deposited on the semiconductor stack 204. A height of the UBM 206 may be, as shown, greater than about 50 μm, significantly larger than a typical height of about 14 μm, to provide sufficient support for later processing operations (including the underfill operation below). The UBM may be formed on the semiconductor stack 204 and substrate 202 using lithographic processes that include, for example, insulator deposition, etching to form the UBM recesses, deposition of the UBM material, and removal of the insulator after deposition.

The UBM 206 may be attached to a frame 210 via a temporary adhesive layer 208. The frame 210 may be formed from a metal or ceramic (e.g., FR4). The frame 210 may be thick enough to support the LED package 200a during later processing, for example, greater than about 600 μm.

The temporary adhesive layer 208 may include a pressure sensitive adhesive layer 208a and a thermal release adhesive 208b. The UBM 206 may be attached to the pressure sensitive adhesive layer 208a. The pressure sensitive adhesive layer 208a may have a thickness of about 6 μm to about 25 μm, for example. The frame 210 may be attached to the thermal release adhesive 208b. The thermal release adhesive 208b may be about 40 μm, for example.

FIG. 2B illustrates a cross-sectional view of an LED package during fabrication after FIG. 2A, in accordance with some examples. At the operation shown in FIG. 2B, a Silicone Molding Compound (SMC) 212 may be applied to the LED package 200b shown in FIG. 2A. The SMC 212 may extend to about 25 μm to about 100 μm above the top surface of the substrate 202.

FIG. 2C illustrates a cross-sectional view of an LED package during fabrication after FIG. 2B, in accordance with some examples. FIG. 2C shows the LED package 200c after several processes have been performed. In particular, a removal process such as microbid blasting (MBB) may be used to remove the SMC 212 above the substrate 202, as well as a majority of the SMC 212 between adjacent LED die. As shown in FIG. 2C, at least some of the underfill 212a may remain between adjacent semiconductor stacks 204 after the MBB process. A laser lift off (LLO) process may be used to remove the sapphire after MBB process. This process decomposes top layer of GaN of the semiconductor stack 204, forming N gas and a thin liquid Ga layer. The N gas formation allows the substrate 202 to be removed. A water or alkaline solution may be used to remove the Ga layer, leaving the semiconductor stack 204, as well as the SMC 212 under the semiconductor stack 204 as underfill 212a. Unlike other semiconductor molding processes that may be relatively vulnerable to successive processes (e.g., later processing using a laser that operates at 450 nm, which may destroy certain types of epoxy resin), the use of a relatively thick silicone molding compound layer as underfill (due to the height of the UBM 206) may provide the desired support after the substrate 202 has been removed.

FIG. 2D illustrates a cross-sectional view of an LED package during fabrication after FIG. 2C, in accordance with some examples. FIG. 2D shows the LED package 200d after several processes have been performed. In particular, a conversion layer 214 may be formed on the semiconductor stack 204, and a sacrificial layer 216 may be formed on the conversion layer 214 using lamination processes (e.g., insulator deposition, layer deposition, insulator removal). The conversion layer 214 may be, for example, a phosphor layer to convert the light emitted by the semiconductor stack 204 to light of one or more other wavelengths, such as white light. In this case, the conversion layer 214 may be, for example a phosphor in silicone or phosphor in the form of ceramic yttrium aluminum garnet (YAG) phosphor and may be about 50 μm to about 100 μm. In other embodiments, a conversion layer 214 may not be used.

FIG. 2E illustrates a cross-sectional view of an LED package during fabrication after FIG. 2D, in accordance with some examples. In FIG. 2D, a reflective material 218 may be deposited to form the LED package 200e. The reflective material 218 may be deposited sufficiently to fill the area between the adjacent LED die. The reflective material 218 may be reflective (e.g., greater than about 94%) at the wavelengths emitted by the semiconductor stack 204 and the conversion layer 214. The reflective material 218 may be formed, for example, from liquid silicone, which may contain titanium oxide (TiO2) or a silicone molding compound with TiO2. Alternatively, a multilayer structure (such as a distributed Bragg reflector) may be deposited using by atomic layer deposition (ALD) processes to provide the desired reflection. The addition reflective material 218 may create a top emitter LED structure to be formed.

FIG. 2F illustrates a cross-sectional view of an LED package during fabrication after FIG. 2E, in accordance with some examples. In FIG. 2E, the reflective material 218 on top of the sacrificial layer 216 as well as the sacrificial layer 216 should be removed to form the LED package 200f. The reflective material 218 and the sacrificial layer 216 may be removed by a process such grinding, air pressure blasting, MBB, or planarization depending on the reflective material 218 used. For example, air pressure blasting may be used when the silicone molding compound is used as the reflective material 218, while planarization may be used when liquid silicone is used as the reflective material 218.

FIG. 2G illustrates a cross-sectional view of an LED package during fabrication after FIG. 2F, in accordance with some examples. In FIG. 2G, a portion of the reflective material 218 may be removed to form the LED package 200g. The portion of the reflective material 218 removed may be between the adjacent LED die from the top of the reflective material 218 to the temporary adhesive layer 208 to form a recess 220. The portion of the reflective material 218 may be removed by a physical mechanism such as sawing through the reflective material 218, for example, or a chemical mechanism such as chemically etching the reflective material 218.

FIG. 2H illustrates a cross-sectional view of an LED package during fabrication after FIG. 2G, in accordance with some examples. In FIG. 2H, a lens (or microlens) 222 may be attached to the remaining portion of the reflective material 218 to form the LED package 200h. In some embodiments, the lens 222 may not be added to the structure. Although shown as being attached to only the reflective material 218 over one the LED package 200h, lenses may be formed over each LED package 200h.

FIG. 2I illustrates a cross-sectional view of an LED package during fabrication after FIG. 2H, in accordance with some examples. In FIG. 2I, the LED package 200h may be placed in a thermal reflow oven to allow the frame 210 to be removed to form the LED package 200i. In some embodiments, the LED package 200h may be heated at a relatively low temperature (e.g., 200° C.) for a predetermined amount of time (e.g., a few minutes) to cure (activate release of) the thermal release adhesive 208b. This allows the frame 210 to be mechanically separated from the temporary adhesive layer 208.

FIG. 2J illustrates a cross-sectional view of an LED package during fabrication after FIG. 2I, in accordance with some examples. In FIG. 2J, the temporary adhesive layer 208 may be mechanically removed (e.g., peeled off) from the LED package 200i to form the LED package 200j. The individual LED dice may be separated thereafter.

This allows, as shown in FIGS. 2A-2J, an array of the LEDs to be created without soldering the LEDs to a ceramic (e.g., AlN/AlO) tile or MCPCB for heat dissipation. The LEDs may be disposed on a tape instead of soldering to the ceramic, underfill may be applied and the excess underfill material removed, and laser lift off of the sapphire substrate from the epitaxial layers. The thickness of underfill used to stabilize the LED structure is thinner than the substrate, decreasing the overall thickness and cost of the structure. Further processes include phosphor attachment, side coating, sawing and tape removal. Each individual LED package may include a thin-film flip-chip (TFFC) LED as well as additional optical components, if desired, without a growth substrate. The optical components may include, for example, a phosphor layer over the LED, a reflecting side coating that allows a top emitter structure to be fabricated, and optical elements (such as lenses) on top of each LED package. The phosphor layer may absorb the light generated by the active region of the semiconductor stack and reemit the light at a different wavelength (e.g., to provide white light).

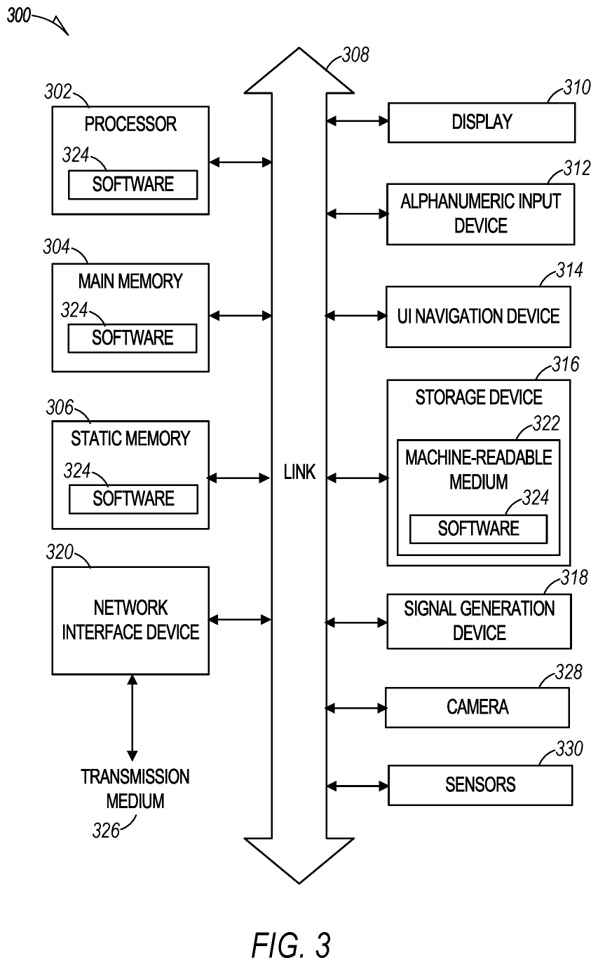

FIG. 3 illustrates an example of an electronic device in accordance with some embodiments. The electronic device 300 may be a mobile device such as a laptop computer (PC), a tablet PC, or a smart phone, for example, an automotive device, or a dedicated electronic apparatus, such as a camera, for example. Various elements may be provided on the PCB indicated above. Examples, as described herein, may include, or may operate on, logic or a number of components, modules, or mechanisms. Modules and components are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” (and “component”) is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

The electronic device 300 may include a hardware processor (or equivalently processing circuitry) 302 (e.g., a central processing unit (CPU), a GPU, a hardware processor core, or any combination thereof), a main memory 304 and a static memory 306, some or all of which may communicate with each other via an interlink (e.g., bus) 308. The main memory 304 may contain any or all of removable storage and non-removable storage, volatile memory or non-volatile memory. The electronic device 300 may further include a display 310 such as a video display, an alphanumeric input device 312 (e.g., a keyboard), and a user interface (UI) navigation device 314 (e.g., a mouse). In an example, the display 310, input device 312 and UI navigation device 314 may be a touch screen display. The electronic device 300 may additionally include a storage device (e.g., drive unit) 316, a signal generation device 318 (e.g., a speaker), a network interface device 320, one or more cameras 328, and one or more sensors 330, such as a global positioning system (GPS) sensor, compass, accelerometer, or other sensor such as those described herein. The electronic device 300 may further include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 316 may include a non-transitory machine readable medium 322 (hereinafter simply referred to as machine readable medium) on which is stored one or more sets of data structures or instructions 324 (e.g., software) embodying or utilized by any one or more of the techniques or functions described herein. The non-transitory machine readable medium 322 is a tangible medium. A storage device 316 that includes the non-transitory machine-readable medium should not be construed as that either the device or the machine-readable medium is itself incapable of having physical movement. The instructions 324 may also reside, completely or at least partially, within the main memory 304, within static memory 306, and/or within the hardware processor 302 during execution thereof by the electronic device 300. While the machine readable medium 322 is illustrated as a single medium, the term “machine readable medium” may include a single medium or multiple media (e.g., a centralized or distributed database, and/or associated caches and servers) configured to store the one or more instructions 324.

The term “machine readable medium” may include any medium that is capable of storing, encoding, or carrying instructions for execution by the electronic device 300 and that cause the electronic device 300 to perform any one or more of the techniques of the present disclosure, or that is capable of storing, encoding or carrying data structures used by or associated with such instructions. Non-limiting machine-readable medium examples may include solid-state memories, and optical and magnetic media. Specific examples of machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks.

The instructions 324 may further be transmitted or received over a communications network using a transmission medium 326 via the network interface device 320 utilizing any one of a number of wireless local area network (WLAN) transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks. Communications over the networks may include one or more different protocols, such as Institute of Electrical and Electronics Engineers (IEEE) 802.11 family of standards known as Wi-Fi, IEEE 802.16 family of standards known as WiMax, IEEE 802.15.4 family of standards, a Long Term Evolution (LTE) family of standards, a Universal Mobile Telecommunications System (UMTS) family of standards, peer-to-peer (P2P) networks, a next generation (NG)/5th generation (5G) standards among others. In an example, the network interface device 320 may include one or more physical jacks (e.g., Ethernet, coaxial, or phone jacks) or one or more antennas to connect to the transmission medium 326.

Note that the term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” or “processor” as used herein thus refers to, is part of, or includes circuitry capable of sequentially and automatically carrying out a sequence of arithmetic or logical operations, or recording, storing, and/or transferring digital data. The term “processor circuitry” or “processor” may refer to one or more application processors, one or more baseband processors, a physical central processing unit (CPU), a single-or multi-core processor, and/or any other device capable of executing or otherwise operating computer-executable instructions, such as program code, software modules, and/or functional processes.

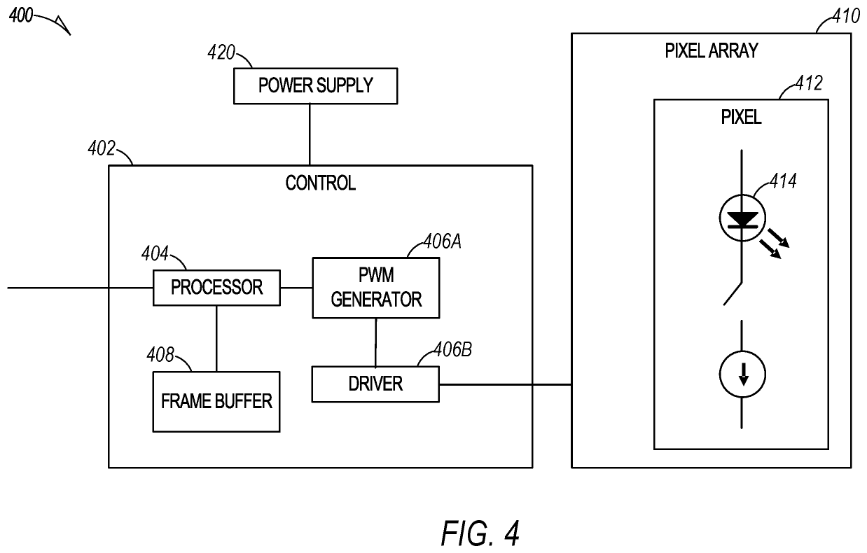

FIG. 4 illustrates an example lighting system, according to some embodiments. As above, some of the elements shown in the lighting system 400 may not be present, while other additional elements may be disposed in the lighting system 400. The lighting system 400 may provide lighting based on an image captured as described in FIG. 1, or may be independently generated based on stored information. For example, the lighting system 400 may include a controller 402 that controls display of an image using a pixel array 410 that contains multiple individual pixels 412.

In some embodiments, some or all of the components described as the controller 402 may be disposed on a backplane such as, for example, a compound metal oxide semiconductor (CMOS) backplane. The controller 402 may be coupled to or include one or more processors 404. The controller 402 may receive image data and inquiries from the one or more processors 404, if external to the controller 402. In this case, the controller 402 may further provide feedback to the one or more processors 404. The one or more processors 404 may receive image data via a digital interface and may process the image data to control a PWM generator 406a, for example, controlling PWM duty cycles and/or turn-on times for causing the lighting system 400 to produce the images indicated by the image data.

The controller 402 may further include a frame buffer 408. The frame buffer 408 may store one or more images prior the one or more processors 404 and store the indications for implementation by the one or more processors 404.

The PWM generator 406a may be controlled by the one or more processors 404 and may produce PWM signals in accordance with the indications. The PWM generator 406a may be connected to a driver 406b to drive the pixel array 410 so that the pixels 412 provide desired intensities of light.

Each pixel 412 may include one or more LEDs 414. The LEDs 414 may be different colors and may be controlled individually or in groups. As shown, the pixel 412 may include, for each pixel 412 or LED 414, a PWM switch, and a current source. The pixel 412 may be driven by the driver 406b. The PWM signal from the PWM generator 406a may cause the PWM switch to open and close in accordance with the value of the PWM signal. The signal corresponding to the intensities of light may cause the current source to produce a current flow to cause the pixel 412 to produce the corresponding intensities of light.

The lighting system 400 may further include a power supply 420. In some embodiments, the power supply 420 may produce power for the controller 402.

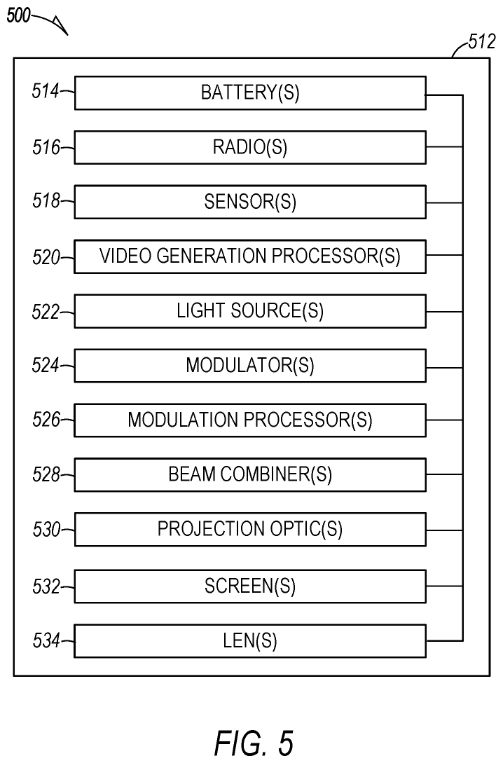

FIG. 5 shows a block diagram of an example of a system, according to some embodiments. The system 500 may provide augmented reality (AR)/virtual reality (VR) functionality using LEDs. The system 500 can include a wearable housing 512, such as a headset or goggles. The housing 512 can mechanically support and house the elements detailed below. In some examples, one or more of the elements detailed below can be included in one or more additional housings that can be separate from the wearable housing 512 and couplable to the wearable housing 512 wirelessly and/or via a wired connection. For example, a separate housing can reduce the weight of wearable goggles, such as by including batteries, radios, and other elements. The housing 512 can include one or more batteries 514, which can electrically power any or all of the elements detailed below. The housing 512 can include circuitry that can electrically couple to an external power supply, such as a wall outlet, to recharge the batteries 514. The housing 512 can include one or more radios 516 to communicate wirelessly with a server or network via a suitable protocol, such as WiFi.

The system 500 can include one or more sensors 518, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 518 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an AR system, one or more of the sensors 518 can capture a real-time video image of the surroundings proximate a user.

The system 500 can include one or more video generation processors 520. The one or more video generation processors 520 can receive scene data that represents a three-dimensional scene, such as a set of position coordinates for objects in the scene or a depth map of the scene. This data may be received from a server and/or a storage medium. The one or more video generation processors 520 can receive one or more sensor signals from the one or more sensors 518. In response to the scene data, which represents the surroundings, and at least one sensor signal, which represents the location and/or orientation of the user with respect to the surroundings, the one or more video generation processors 520 can generate at least one video signal that corresponds to a view of the scene. In some examples, the one or more video generation processors 520 can generate two video signals, one for each eye of the user, that represent a view of the scene from a point of view of the left eye and the right eye of the user, respectively. In some examples, the one or more video generation processors 520 can generate more than two video signals and combine the video signals to provide one video signal for both eyes, two video signals for the two eyes, or other combinations.

The system 500 can include one or more light sources 522 that can provide light for a display of the system 500. Suitable light sources 522 can include the LEDs above, for example. The one or more light sources 522 can include light-producing elements having different colors or wavelengths. For example, a light source can include a red light-emitting diode that can emit red light, a green light-emitting diode that can emit green light, and a blue light-emitting diode that can emit blue right. The red, green, and blue light combine in specified ratios to produce any suitable color that is visually perceptible in a visible portion of the electromagnetic spectrum.

The system 500 can include one or more modulators 524. The modulators 524 can be implemented in one of at least two configurations. In a first configuration, the modulators 524 can include circuitry that can modulate the light sources 522 directly. For example, the light sources 522 can include an array of light-emitting diodes, and the modulators 524 can directly modulate the electrical power, electrical voltage, and/or electrical current directed to each light-emitting diode in the array to form modulated light. The modulation can be performed in an analog manner and/or a digital manner. In some examples, the light sources 522 can include an array of red light-emitting diodes, an array of green light-emitting diodes, and an array of blue light-emitting diodes, and the modulators 524 can directly modulate the red light-emitting diodes, the green light-emitting diodes, and the blue light-emitting diodes to form the modulated light to produce a specified image.

In a second configuration, the modulators 524 can include a modulation panel, such as a liquid crystal panel. The light sources 522 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 524 can include multiple modulation panels that can modulate different colors of light. For example, the modulators 524 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 524 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The system 500 can include one or more modulation processors 526, which can receive a video signal, such as from the one or more video generation processors 520, and, in response, can produce an electrical modulation signal. For configurations in which the modulators 524 directly modulate the light sources 522, the electrical modulation signal can drive the light sources 522. For configurations in which the modulators 524 include a modulation panel, the electrical modulation signal can drive the modulation panel.

The system 500 can include one or more beam splitters 528 (and/or beam combiners), which can combine light beams of different colors to form a single multi-color beam. For configurations in which the light sources 522 can include multiple light-emitting diodes of different colors, the system 500 can include one or more wavelength-sensitive (e.g., dichroic) beam splitters 528 that can combine the light of different colors to form a single multi-color beam.

The system 500 can direct the modulated light toward the eyes of the viewer in one of at least two configurations. In a first configuration, the system 500 can function as a projector, and can include suitable projection optics 530 that can project the modulated light onto one or more screens 532. The screens 532 can be located a suitable distance from an eye of the user. The system 500 can optionally include one or more lenses 534 that can locate a virtual image of a screen 532 at a suitable distance from the eye, such as a close-focus distance, such as 500 mm, 750 mm, or another suitable distance. In some examples, the system 500 can include a single screen 532, such that the modulated light can be directed toward both eyes of the user. In some examples, the system 500 can include two screens 532, such that the modulated light from each screen 532 can be directed toward a respective eye of the user. In some examples, the system 500 can include more than two screens 532. In a second configuration, the system 500 can direct the modulated light directly into one or both eyes of a viewer. For example, the projection optics 530 can form an image on a retina of an eye of the user, or an image on each retina of the two eyes of the user.

For some configurations of AR systems, the system 500 can include at least a partially transparent display, such that a user can view the user's surroundings through the display. For such configurations, the AR system can produce modulated light that corresponds to the augmentation of the surroundings, rather than the surroundings itself. For example, in the example of a retailer showing a chair, the AR system can direct modulated light, corresponding to the chair but not the rest of the room, toward a screen or toward an eye of a user.

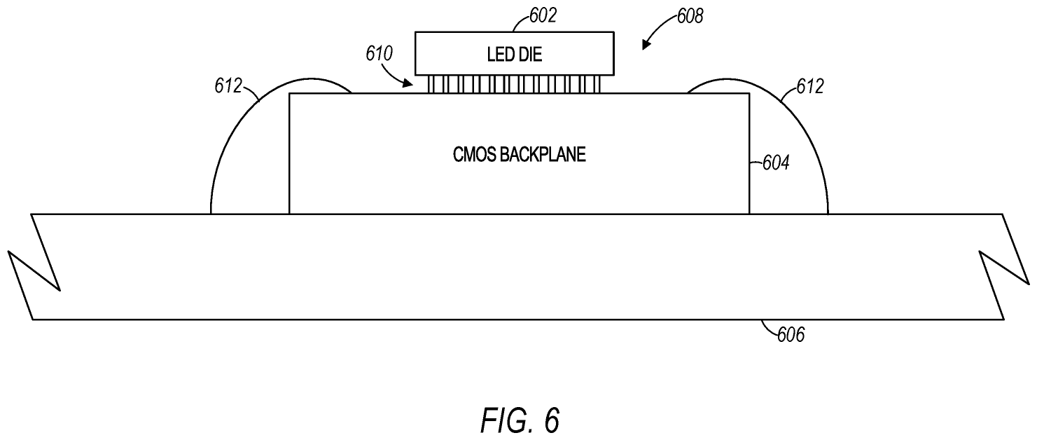

FIG. 6 illustrates an example hardware arrangement for implementing the above disclosed subject matter, according to some embodiments. In particular, the hardware arrangement 600 may include an integrated LED 608. The integrated LED 608 may include an LED die 602 that contains the LED array(s) and a backplane, such as a CMOS backplane 604. The LED die 602 may be coupled to the CMOS backplane 604 by one or more interconnects 610, where the interconnects 610 may provide for transmission of signals between the LED die 602 and the CMOS backplane 604. The interconnects 610 may comprise one or more solder bump joints, one or more copper pillar bump joints, other types of interconnects known in the art, or some combination thereof.

The LED die 602 may include circuitry to implement the micro-LED array. In particular, the LED die 602 may include a plurality of micro-LEDs. The LED die 602 may include a shared active layer and a shared substrate for the micro-LED array, and thereby the micro-LED array may be a monolithic micro-LED array. Each micro-LED of the micro-LED array may include an individual segmented active layer and/or substrate. In some embodiments, the LED die 602 may further include switches and current sources to drive the micro-LED array. In other embodiments, the PWM switches and the current sources may be included in the CMOS backplane 604.

The CMOS backplane 604 may include circuitry to implement the control module and/or the LED power supply. The CMOS backplane 604 may utilize the interconnects 610 to provide the micro-LED array with the PWM signals and the signals for the intensity for causing the micro-LED array to produce light in accordance with the PWM signals and the intensity. Because of the relatively large number and density of connections to drive the micro-LED array compared to standard LED arrays, different embodiments may be used to electrically connect the CMOS backplane 604 and the LED die 602. Either the bonding pad pitch of the CMOS backplane 604 may be the same as the pitch of bonding pads in the micro-LED array, or the bonding pad pitch of the CMOS backplane 604 may be larger than the pitch of bonding pads in the micro-LED array.

The hardware arrangement 600 may further include a PCB 606. The PCB 606 may include circuitry to implement various functionality described herein. The PCB 606 may be coupled to the CMOS backplane 604. For example, the PCB 606 may be coupled to the CMOS backplane 604 via one or more wire bonds 612. The PCB 606 and the CMOS backplane 604 may exchange image data, power, and/or feedback via the coupling, among other signals.

As shown, the micro-LEDs and circuitry supporting the micro-LED array can be packaged and include a submount or printed circuit board for powering and controlling light production by the micro-LEDs. The PCB supporting the micro-LED array may include electrical vias, heat sinks, ground planes, electrical traces, and flip chip or other mounting systems. The submount or PCB may be formed of any suitable material, such as ceramic, silicon, aluminum, etc. If the submount material is conductive, an insulating layer may be formed over the substrate material, and a metal electrode pattern formed over the insulating layer for contact with the micro-LED array. The submount can act as a mechanical support, providing an electrical interface between electrodes on the micro-LED array and a power supply, and also provide heat sink functionality.

As above, a variety of applications may be supported by micro-LED arrays. Such applications may include a stand-alone applications to provide general illumination (e.g., within a room or vehicle) or to provide specific images. In addition to devices such as a luminaire, projector, mobile device, the system may be used to provide either augmented reality (AR) and virtual reality (VR)-based applications. Visualization systems, such as VR and AR systems, are becoming increasingly more common across numerous fields such as entertainment, education, medicine, and business. Various types of devices may be used to provide AR/VR to users, including headsets, glasses, and projectors. Such an AR/VR system may include components similar to those described above: the micro-LED array, a display or screen (which may include touchscreen elements), a micro-LED array controller, sensors, and a controller, among others. The AR/VR components can be disposed in a single structure, or one or more of the components shown can be mounted separately and connected via wired or wireless communication. Power and user data may be provided to the controller. The user data input can include information provided by audio instructions, haptic feedback, eye or pupil positioning, or connected keyboard, mouse, or game controller. The sensors may include cameras, depth sensors, audio sensors, accelerometers, two or three axis gyroscopes and other types of motion and/or environmental/wearer sensors that provide the user input data. Other sensors can include but are not limited to air pressure, stress sensors, temperature sensors, or any other suitable sensors for local or remote environmental monitoring. In some embodiments, the control input can include detected touch or taps, gestural input, or control based on headset or display position. As another example, based on the one or more measurement signals from one or more gyroscope or position sensors that measure translation or rotational movement, an estimated position of the AR/VR system relative to an initial position can be determined.

In some embodiments, the controller may control individual micro-LEDs or one or more micro-LED pixels (groups of micro-LEDs) to display content (AR/VR and/or non-AR/VR) to the user while controlling other micro-LEDs and sensors used in eye tracking to adjust the content displayed. Content display micro-LEDs may be designed to emit light within the visible band (approximately 400 nm to 780 nm) while micro-LEDs used for tracking may be designed to emit light in the IR band (approximately 780 nm to 2,200 nm). In some embodiments, the tracking micro-LEDs and content micro-LEDs may be simultaneously active. In some embodiments, the tracking micro-LEDs may be controlled to emit tracking light during a time period that content micro-LEDs are deactivated and are thus not displaying content to the user. The AR/VR system can incorporate optics, such as those described above, and/or an AR/VR display, for example to couple light emitted by micro-LED array onto the AR/VR display.

In some embodiments, the AR/VR controller may use data from the sensors to integrate measurement signals received from the accelerometers over time to estimate a velocity vector and integrate the velocity vector over time to determine an estimated position of a reference point for the AR/VR system. In other embodiments, the reference point used to describe the position of the AR/VR system can be based on depth sensor, camera positioning views, or optical field flow. Based on changes in position, orientation, or movement of the AR/VR system, the system controller can send images or instructions the light emitting array controller. Changes or modification the images or instructions can also be made by user data input, or automated data input.

In general, in a VR system, a display can present to a user a view of scene, such as a three-dimensional scene. The user can move within the scene, such as by repositioning the user's head or by walking. The VR system can detect the user's movement and alter the view of the scene to account for the movement. For example, as a user rotates the user's head, the system can present views of the scene that vary in view directions to match the user's gaze. In this manner, the VR system can simulate a user's presence in the three-dimensional scene. Further, a VR system can receive tactile sensory input, such as from wearable position sensors, and can optionally provide tactile feedback to the user.

In an AR system, on the other hand, the display can incorporate elements from the user's surroundings into the view of the scene. For example, the AR system can add textual captions and/or visual elements to a view of the user's surroundings. For example, a retailer can use an AR system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the AR system can position a virtual chair in a room. The user can stand in the room on a front side of the virtual chair location to view the front side of the chair. The user can move in the room to an area behind the virtual chair location to view a back side of the chair. In this manner, the AR system can add elements to a dynamic view of the user's surroundings.

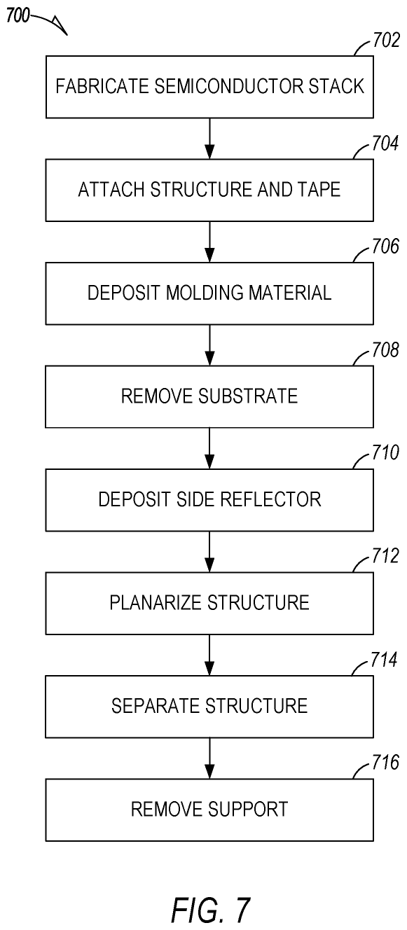

FIG. 7 illustrates an example method of fabricating an illumination, according to some embodiments. Not all of the operations may be undertaken in the method 700, and/or additional operations may be present. The operations may occur in a different order from that indicated in FIG. 7.

At operation 702, a semiconductor stack of the LED structure may be formed as an array via an epitaxial process and tall UBM (greater than about 50 μm) fabricated thereon. The semiconductor stack includes the n-type and p-type semiconductor layers, as well as the active region therebetween in which light is created through electron-hole recombination processes. In some embodiments, the fabrication of the semiconductor stack may include etching of the n-type semiconductor layer to form fins. The semiconductor stack may be formed in any of a number of geometric shapes, such as rectangular, to provide polarized light emission from one or more sidewalls of the semiconductor stack based on waveguiding within the epitaxial semiconductor layers. The semiconductor stack may be formed on a sapphire or other substrate.

After fabrication of the semiconductor stack, the structure containing the semiconductor stack, substrate, and UBM may be placed on a temporary adhesive layer that is attached to a metal or ceramic frame at operation 704. The temporary adhesive layer may be attached to the frame using a thermal release adhesive; the structure may be attached to a pressure sensitive adhesive layer of the temporary adhesive layer.

After the structure is placed on a temporary adhesive layer and frame, SMC may be deposited on the structure (and under the UBM) at operation 706. The SMC may be a silicone-based material, for example.

At operation 708, the various portions of the structure present after operation 706 are removed using one or more processes, such as blasting and LLO. The portions include the SMC above the substrate and adjacent to the semiconductor, as well as the substrate itself. The SMC under the semiconductor stack may remain underfill. The amount of underfill may be sufficient to support the thin semiconductor stack during the subsequent processing operations rather than relying on the substrate.

At operation 710, reflective material is deposited on the remaining structure after the various portions of the structure have been removed at operation 708. In some embodiments, a conversion layer and a sacrificial layer may be formed on the epitaxial semiconductor layers of the semiconductor stack using lithographic processes prior to deposition of the reflective material. In any case, the reflective material may be deposited sufficiently to fill the area between the adjacent structures. The reflective material may be selected to be reflective to at least the light emitted by the semiconductor stack

At operation 712, the layers are planarized to expose the top layer of the semiconductor stack (or conversion layer, if present). The reflective material is thus removed from above the semiconductor stack to form the LED die.

At operation 714, LED die in the LED package containing the reflective material are separated. In particular, the reflective material may be sawn through or otherwise removed to separate the array into individual LED die. The reflective material may be maintained on sidewalls of the LED die (at least the semiconductor stack and the conversion layer, if present) after removal from the top. In some embodiments, optics, such as a lens may be attached to the separated LED die.

At operation 716, the temporary adhesive layer and the LED package are separated. The LED package may be placed in a thermal reflow oven to allow the frame to be removed from the temporary adhesive layer, and then the temporary adhesive layer may be peeled off from the bottom of the LED package (formed by the underfill/UBM). This structure may be cleaned or otherwise prepared for connection to control circuitry to control illumination of the LEDs. For example, the LEDs may be individually attached to one or more PCBs containing one or more processors, drivers, and other circuitry as described herein.

While only certain features of the system and method have been illustrated and described herein, many modifications and changes will occur to those skilled in the art. It is, therefore, to be understood that the appended claims are intended to cover all such modifications and changes. Method operations may be performed substantially simultaneously or in a different order.

### EXAMPLES

Example 1 is a method of fabricating a light-emitting diode (LED) device, the method comprising: attaching at least one LED structure to a frame via a temporary adhesive layer, the at least one LED structure containing a semiconductor stack on a growth substrate and under bump metallization (UBM) to provide electrical coupling to at least one semiconductor layer of the semiconductor stack; depositing Silicone Molding Compound (SMC) to at least provide the SMC as underfill between the semiconductor stack and the temporary adhesive layer; removing the growth substrate to form at least one modified LED structure that contains the semiconductor stack, the UBM, and the underfill on the temporary adhesive layer; processing the at least one modified LED structure to form at least one LED die; and removing the temporary adhesive layer and frame from the at least one LED die of the LED device.

In Example 2, the subject matter of Example 1 includes, μm.

In Example 3, the subject matter of Examples 1-2 includes, wherein: the at least one LED structure comprises a plurality of LED structures, the SMC or Silicone mixed with TiO2 is deposited between adjacent LED structures of the plurality of LED structures, and the SMC deposited between the adjacent LED structures is removed prior to forming the at least one LED die.

In Example 4, the subject matter of Example 3 includes, wherein: the semiconductor stack is formed from gallium nitride (GaN), the SMC is removed using microbid blasting (MBB), the growth substrate is removed using laser lift off (LLO), and the method further comprises removing a liquid gallium layer formed during the LLO.

In Example 5, the subject matter of Examples 1-4 includes, wherein: the temporary adhesive layer comprises a pressure sensitive adhesive layer and a thermal release adhesive, the frame is attached to the thermal release adhesive, and attaching the at least one LED structure to the temporary adhesive layer comprises attaching the at least one LED structure to the pressure sensitive adhesive layer.

In Example 6, the subject matter of Example 5 includes, wherein removing the temporary adhesive layer comprises: heating the thermal release adhesive to separate the frame from the thermal release adhesive, and mechanically separating the at least one LED structure from the pressure sensitive adhesive layer after separation of the frame from the thermal release adhesive.

In Example 7, the subject matter of Examples 1-6 includes, wherein: the at least one modified LED structure comprises a plurality of modified LED structures, and the processing comprises depositing a reflective material between adjacent modified LED structures and removing a portion of the reflective material to separate the adjacent modified LED structures to form LED dice while maintaining the reflective material on sidewalls of each of the adjacent modified LED structures.

In Example 8, the subject matter of Example 7 includes, wherein: the depositing comprises depositing the reflective material above the modified LED structures, and the removing the reflective material comprises: removing the reflecting material deposited above the modified LED structures using at least one type of removal method selected from methods including planarization and blasting dependent on a type of the reflecting material, and sawing through the portion of the reflective material between each of the adjacent modified LED structures.

In Example 9, the subject matter of Examples 1-8 includes, wherein the processing the at least one modified LED structure comprises depositing a conversion layer on the semiconductor stack of the at least one modified LED structure to convert light of a first wavelength emitted by the semiconductor stack to light of a second wavelength.

In Example 10, the subject matter of Example 9 includes, wherein: the at least one modified LED structure comprises a plurality of modified LED structures, and the processing further comprises: depositing a reflective material between adjacent modified LED structures and on the conversion layer of each of the modified LED structures, and removing the reflective material on the conversion layer of each of the modified LED structures and a portion of the reflective material between adjacent modified LED structures to separate the adjacent modified LED structures to form LED dice while maintaining the reflective material on sidewalls of each of the adjacent modified LED structures.

In Example 11, the subject matter of Example 10 includes, wherein the processing further comprises attaching a lens to each of the LED dice.

Example 12 is a method of fabricating a light-emitting diode (LED) device, the method comprising: attaching at least one LED structure to a frame via a temporary adhesive layer, the LED structures containing a semiconductor stack on a growth substrate and under bump metallization (UBM) to provide electrical coupling to at least one semiconductor layer of the semiconductor stack; depositing Silicone Molding Compound (SMC) to at least provide the SMC as underfill between the semiconductor stack and the temporary adhesive layer; removing the growth substrate to retain the semiconductor stack, the UBM, and the underfill on the temporary adhesive layer; providing reflective material between the LED structures after removing the growth substrate; and removing the temporary adhesive layer and frame after providing the reflective material of the LED device.

In Example 13, the subject matter of Example 12 includes, wherein: the SMC is deposited between adjacent LED structures, and the SMC deposited between the adjacent LED structures is removed prior to removing the temporary adhesive layer.

In Example 14, the subject matter of Example 13 includes, wherein: the semiconductor stack is formed from gallium nitride (GaN), the SMC is removed using microbid blasting (MBB), the growth substrate is removed using laser lift off (LLO), and the method further comprises removing a liquid gallium layer formed during the LLO.

In Example 15, the subject matter of Examples 12-14 includes, wherein: the temporary adhesive layer comprises a pressure sensitive adhesive layer and a thermal release adhesive, the frame is attached to the thermal release adhesive, and attaching the LED structures to the temporary adhesive layer comprises attaching the LED structures to the pressure sensitive adhesive layer.

In Example 16, the subject matter of Example 15 includes, wherein removing the temporary adhesive layer comprises: heating the thermal release adhesive in a thermal reflow oven to activate release of the thermal release adhesive and then separating the frame from the thermal release adhesive, and mechanically separating the LED structures from the pressure sensitive adhesive layer after separation of the frame from the thermal release adhesive.

In Example 17, the subject matter of Examples 12-16 includes, removing a portion of the reflective material to separate the LED structures while maintaining the reflective material on sidewalls of each of adjacent LED structures.

In Example 18, the subject matter of Examples 12-17 includes, depositing a conversion layer on the semiconductor stack of each LED structure prior to depositing the reflective material, the conversion layer to convert light of a first wavelength emitted by the semiconductor stack to light of a second wavelength.

In Example 19, the subject matter of Example 18 includes, removing the reflective material on the conversion layer of each LED structure and a portion of the reflective material between LED structures to separate the LED structures while maintaining the reflective material on sidewalls of each of adjacent LED structures.

In Example 20, the subject matter of Example 19 includes, attaching a lens to each of the LED structures after separating the LED structures and prior to removing the temporary adhesive layer.

Example 21 is a light-emitting diode (LED) die array comprising a plurality of LED dice, each LED die comprising: a semiconductor stack that includes, an n-type semiconductor, a p-type semiconductor, and an active region sandwiched between the n-type semiconductor and the p-type semiconductor, the semiconductor stack lacking a growth substrate; under bump metallization (UBM) electrically coupled to the p-type semiconductor and the n-type semiconductor; and molding compound disposed under the semiconductor stack adjacent to the UBM to substantially completely fill a space between the UBM as underfill and provide mechanical support for the LED die.

In Example 22, the subject matter of Example 21 includes, reflective material disposed on sidewalls of each of the plurality of LED dice.

In Example 23, the subject matter of Examples 21-22 includes, a conversion layer contacting a top of the semiconductor stack of each LED die, the conversion layer configured to convert light of a first wavelength emitted by the semiconductor stack to light of a second wavelength.

In Example 24, the subject matter of Examples 21-23 includes, a lens attached to each of the plurality of LED dice.

In Example 25, the subject matter of Examples 21-24 includes, μm.

Example 26 is at least one machine-readable medium including instructions that, when executed by processing circuitry, cause the processing circuitry to perform operations to implement of any of Examples 1-25.

Example 27 is an apparatus comprising means to implement of any of Examples 1-25.

Example 28 is a system to implement of any of Examples 1-25.

Example 29 is a method to implement of any of Examples 1-25.

Although an embodiment has been described with reference to specific example embodiments, it will be evident that various modifications and changes may be made to these embodiments without departing from the broader scope of the present disclosure. Accordingly, the specification and drawings are to be regarded in an illustrative rather than a restrictive sense. The accompanying drawings that form a part hereof show, by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

The subject matter may be referred to herein, individually and/or collectively, by the term “embodiment” merely for convenience and without intending to voluntarily limit the scope of this application to any single inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, UE, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects. For example, the term “a processor” configured to carry out specific operations includes both a single processor configured to carry out all of the operations as well as multiple processors individually configured to carry out some or all of the operations (which may overlap) such that the combination of processors carry out all of the operations. Further, the term “includes” may be considered to be interpreted as “includes at least”the elements that follow.

The Abstract of the Disclosure is submitted with the understanding that it will not be used to interpret or limit the scope or meaning of the claims. In addition, in the foregoing Detailed Description, it may be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

1. A method of fabricating a light-emitting diode (LED) device, the method comprising:
attaching at least one LED structure to a frame via a temporary adhesive layer, the at least one LED structure containing a semiconductor stack on a growth substrate and under bump metallization (UBM) to provide electrical coupling to at least one semiconductor layer of the semiconductor stack;
depositing Silicone Molding Compound (SMC) to at least provide the SMC as underfill between the semiconductor stack and the temporary adhesive layer;
removing the growth substrate to form at least one modified LED structure that contains the semiconductor stack, the UBM, and the underfill on the temporary adhesive layer;
processing the at least one modified LED structure to form at least one LED die; and
removing the temporary adhesive layer and the frame from the at least one LED die of the LED device.

2. The method of claim 1, wherein the UBM has a height of at least about 50 μm.

3. The method of claim 1, wherein:
the at least one LED structure comprises a plurality of LED structures,
the SMC is deposited between adjacent LED structures of the plurality of LED structures, and
the SMC deposited between the adjacent LED structures is removed prior to forming the at least one LED die.

4. The method of claim 3, wherein:
the semiconductor stack is formed from gallium nitride (GaN),
the SMC is removed using microbid blasting (MBB),
the growth substrate is removed using laser lift off (LLO), and
the method further comprises removing a liquid gallium layer formed during the LLO.

5. The method of claim 1, wherein:
the temporary adhesive layer comprises a pressure sensitive adhesive layer and a thermal release adhesive, and
attaching the at least one LED structure to the frame comprises attaching the at least one LED structure to the pressure sensitive adhesive layer.

6. The method of claim 5, wherein removing the temporary adhesive layer comprises:
heating the thermal release adhesive to separate the frame from the thermal release adhesive, and
mechanically separating the at least one LED structure from the pressure sensitive adhesive layer after separation of the frame from the thermal release adhesive.

7. The method of claim 1, wherein:
the at least one modified LED structure comprises a plurality of modified LED structures, and
the processing comprises depositing a reflective material between adjacent modified LED structures and removing a portion of the reflective material to separate the adjacent modified LED structures to form LED dice while maintaining the reflective material on sidewalls of each of the adjacent modified LED structures.

8. The method of claim 7, wherein:
the depositing comprises depositing the reflective material above the modified LED structures, and
the removing the reflective material comprises:
removing the reflecting material deposited above the modified LED structures using at least one type of removal method selected from methods including planarization and blasting that is dependent on a type of the reflecting material, and
using a physical mechanism to remove the portion of the reflective material between each of the adjacent modified LED structures.

9. The method of claim 1, wherein the processing the at least one modified LED structure comprises depositing a conversion layer on the semiconductor stack of the at least one modified LED structure to convert light of a first wavelength emitted by the semiconductor stack to light of a second wavelength.

10. The method of claim 9, wherein:
the at least one modified LED structure comprises a plurality of modified LED structures, and
the processing further comprises:
depositing a reflective material between adjacent modified LED structures and on the conversion layer of each of the modified LED structures, and
removing the reflective material on the conversion layer of each of the modified LED structures and a portion of the reflective material between adjacent modified LED structures to separate the adjacent modified LED structures to form LED dice while maintaining the reflective material on sidewalls of each of the adjacent modified LED structures.

11. The method of claim 10, wherein the processing further comprises attaching a lens to each LED die.

12. A method of fabricating a light-emitting diode (LED) device, the method comprising:
attaching at least one LED structure to a frame via a temporary adhesive layer, the LED structures containing a semiconductor stack on a growth substrate and under bump metallization (UBM) to provide electrical coupling to at least one semiconductor layer of the semiconductor stack;
depositing Silicone Molding Compound (SMC) to at least provide the SMC as underfill between the semiconductor stack and the temporary adhesive layer;
removing the growth substrate to retain the semiconductor stack, the UBM, and the underfill on the temporary adhesive layer;
providing reflective material between the LED structures after removing the growth substrate; and
removing the temporary adhesive layer and frame after providing the reflective material of the LED device.

13. The method of claim 12, wherein:
the SMC is deposited between adjacent LED structures, and
the SMC deposited between the adjacent LED structures is removed prior to removing the temporary adhesive layer.

14. The method of claim 13, wherein:
the semiconductor stack is formed from gallium nitride (GaN),
the SMC is removed using microbid blasting (MBB),
the growth substrate is removed using laser lift off (LLO), and
the method further comprises removing a liquid gallium layer formed during the LLO.

15. The method of claim 12, wherein:
the temporary adhesive layer comprises a pressure sensitive adhesive layer and a thermal release adhesive, and
attaching the LED structures to the temporary adhesive layer comprises attaching the LED structures to the pressure sensitive adhesive layer.

16. The method of claim 15, wherein removing the temporary adhesive layer comprises:
heating the thermal release adhesive in a thermal reflow oven to activate release of the thermal release adhesive and then separating the frame from the thermal release adhesive, and
mechanically separating the LED structures from the pressure sensitive adhesive layer after separation of the frame from the thermal release adhesive.

17. The method of claim 12, further comprising removing a portion of the reflective material to separate the LED structures while maintaining the reflective material on sidewalls of each of adjacent LED structures.

18. The method of claim 12, further comprising:
depositing a conversion layer on the semiconductor stack of each LED structure prior to depositing the reflective material, the conversion layer to convert light of a first wavelength emitted by the semiconductor stack to light of a second wavelength; and
removing the reflective material on the conversion layer of each LED structure and a portion of the reflective material between LED structures to separate the LED structures while maintaining the reflective material on sidewalls of each of adjacent LED structures.

19. A light-emitting diode (LED) die array comprising a plurality of LED dice, each LED die comprising:
a semiconductor stack that includes an n-type semiconductor, a p-type semiconductor, and an active region sandwiched between the n-type semiconductor and the p-type semiconductor, the semiconductor stack lacking a growth substrate;
under bump metallization (UBM) electrically coupled to the p-type semiconductor and the n-type semiconductor; and
molding compound disposed under the semiconductor stack adjacent to the UBM to substantially completely fill a space between the UBM as underfill and provide mechanical support for the LED die.

20. The LED die of claim 19, further comprising reflective material disposed on sidewalls of each of the plurality of LED dice.
